(19) United States
(12) Patent Application Publication
(10) Pub. No.: US 2026/0197949 A1
(43) Pub. Date: Jul. 9, 2026

(54) MANUFACTURING METHOD FOR CIRCUIT BOARD STRUCTURE

(71) Applicant: UNIMICRON TECHNOLOGY CORP., Taoyuan City (TW)

(72) Inventor: Wen-Hao CHEN, Taoyuan City (TW)

(73) Assignee: UNIMICRON TECHNOLOGY CORP., Taoyuan City (TW)

(21) Appl. No.: 19/049,929

(22) Filed: Feb. 10, 2025

(30) Foreign Application Priority Data
Jan. 6, 2025 (TW) 114100451

(51) Int. Cl. H05K 3/46; H05K 3/00

(52) U.S. Cl. CPC H05K 3/4644; H05K 3/0047; H05K 2203/06

(57) ABSTRACT

A manufacturing method for a circuit board structure is provided. The manufacturing method for the circuit board structure includes the following steps. A plurality of conductive films are patterned to form a plurality of circuit layers, wherein the circuit layers include a first circuit layer and a second circuit layer. A plurality of dielectric layers are provided, wherein the dielectric layers include a first dielectric layer and a second dielectric layer. The first dielectric layer, the first circuit layer, the second dielectric layer, and the second circuit layer are sequentially stacked on the first basic circuit layer. A lamination process is performed to fixedly attach the first dielectric layer, the first circuit layer, the second dielectric layer, and the second circuit layer to the first basic circuit layer.

### CROSS REFERENCE TO RELATED APPLICATIONS

This Application claims priority of Taiwan Patent Application No. 114100451, filed on Jan. 6, 2025, the entirety of which is incorporated by reference herein.

### BACKGROUND OF THE INVENTION

### Field of the Invention

The present disclosure relates to a manufacturing method for a circuit board structure, and, in particular, it relates to a manufacturing method for a circuit board structure in which a plurality of pre-produced circuit layers are pressed onto a base substrate at one time.

### Description of the Related Art

Circuit board structures usually include a base substrate and a build-up structure. Specifically, one dielectric film and one conductive film can be sequentially stacked on the base substrate. Next, a patterning process is performed on the conductive film to turn the conductive film into a circuit pattern (or a circuit layer) that can achieve specific functions. Finally, the above-mentioned build-up process is performed repeatedly until the entire circuit board structure has the required number of layers as per the design. However, as circuit board structures become increasingly complex and have an increasing number of layers, stacking them layer by layer will take a lot of time. Therefore, while existing methods of manufacturing circuit board structures have gradually met their intended purposes, they do not meet requirements in all respects. Therefore, there is still a need to develop new manufacturing methods for circuit board structures.

### BRIEF SUMMARY OF THE INVENTION

In some embodiments, a manufacturing method for a circuit board structure is provided. The manufacturing method for the circuit board structure includes the following steps. A plurality of conductive films are patterned to form a plurality of circuit layers, wherein the circuit layers include a first circuit layer and a second circuit layer. A plurality of dielectric layers are provided, wherein the dielectric layers include a first dielectric layer and a second dielectric layer. The first dielectric layer, the first circuit layer, the second dielectric layer, and the second circuit layer are sequentially stacked on the first basic circuit layer. A lamination process is performed to fixedly attach the first dielectric layer, the first circuit layer, the second dielectric layer, and the second circuit layer to the first basic circuit layer.

In some embodiments, after performing the lamination process, the manufacturing method for the circuit board structure further includes the following step. A drilling process is performed so that the first circuit layer includes a first portion and a second portion that are disconnected from each other and the second circuit layer includes a third portion and a fourth portion that are disconnected from each other.

In some embodiments, the second portion surrounds the first portion, and the fourth portion surrounds the third portion.

In some embodiments, the first portion or the third portion is a long line, and the second portion or the fourth portion is a rectangular ring line, a circular loop line, a triangular loop line, a polygonal loop line, or a loop line with head and tail disconnected.

In some embodiments, the basic substrate further includes a second basic circuit layer, and the second basic circuit layer is disposed on the core layer relative to the first basic circuit layer.

In some embodiments, the circuit layers include a third circuit layer and a fourth circuit layer. The dielectric layers further include a third dielectric layer and a fourth dielectric layer. The manufacturing method for the circuit board structure further includes the following steps. The third dielectric layer, the third circuit layer, the fourth dielectric layer, and the fourth circuit layer are sequentially stacked on the second basic circuit layer. The laminating process is performed so that the third dielectric layer, the third circuit layer, the fourth dielectric layer, and the fourth circuit layer are fixedly attached to the second basic circuit layer.

In some embodiments, after performing the lamination process, the manufacturing method for the circuit board structure further includes the following step. A drilling process is performed so that the third circuit layer includes a fifth portion and a sixth portion that are disconnected from each other and the fourth circuit layer includes a seventh portion and an eighth portion that are disconnected from each other.

In some embodiments, the sixth portion surrounds the fifth portion, and the eighth portion surrounds the seventh portion.

In some embodiments, after patterning the conductive films, the circuit layers are carried by a plurality of spacers to stack the circuit layers on the first basic circuit layer.

In some embodiments, the process of patterning the conductive films includes a laser etching process.

In some embodiments, the laser etching process includes a solid-state laser.

In some embodiments, a thickness of the plurality of conductive films is between 12 μm and 18 μm.

In some embodiments, a thickness of the plurality of dielectric layers is at least 35 μm.

In some embodiments, the step of performing a lamination process includes the following step. M layers of the plurality of dielectric layers and n layers of the plurality of circuit layers is laminated on one side of the base substrate at one time, wherein m is a positive integer between 2 and 10, and n is a positive integer between 2 and 10.

In some embodiments, m is equal to n.

In some embodiments, the step of performing a lamination process includes the following step. A total of x layers of the plurality of dielectric layers and a total of y layers of the plurality of circuit layers is laminated on two sides of the base substrate at one time, wherein x is a positive integer between 3 and 20, and y is a positive integer between 3 and 20.

In some embodiments, x is equal to y.

In some embodiments, a different number of dielectric layers are formed on two sides of the base substrate.

In some embodiments, a different number of circuit layers are formed on both sides of the base substrate.

In some embodiments, the step of the lamination process is implemented without an adhesive.

The manufacturing method for the circuit board structure of the present disclosure may be applied in a variety of circuit board structures. In order to make the features and advantages of the present disclosure more comprehensible, various embodiments are specially cited hereinafter, together with the accompanying drawings, to be described in detail as follows.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1, 2A, 3, 4, 5A, and 6 are schematic cross-sectional views showing the circuit board structure at different stages of the manufacturing method according to some embodiments of the present disclosure.

FIGS. 2B and 5B are schematic top views showing the circuit layer at different stages of the manufacturing method according to some embodiments of the present disclosure.

### DETAILED DESCRIPTION OF THE INVENTION

The devices of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding elements in order to clearly describe the present disclosure. However, the use of these similar or corresponding reference numerals is only for the purpose of simply and clearly description of some embodiments of the present disclosure, and does not imply any correlation between the different embodiments or structures discussed.

In addition, it should be understood that ordinal numbers such as “first”, “second”, and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name. The claims and the specification may not use the same terms, for example, a first element in the specification may be a second element in the claim.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is there is another structure disposed between the two structures. Moreover, the terms related to bonding and connection may also include embodiments in which both structures are movable, or both structures are fixed. Furthermore, the terms “electrically connected” or “electrically coupled” include any direct and indirect means of electrical connection.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” may still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

It should be understood that, in the following embodiments, features in several different embodiments may be replaced, recombined, and bonded to complete other embodiments without departing from the spirit of the present disclosure. The features of the various embodiments may be used in any combination as long as they do not violate the spirit of the present disclosure or conflict with each other.

Unless otherwise defined, all terms (including technical and scientific terms) used herein have the same meaning as commonly understood by a person of ordinary skill in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

In existing manufacturing methods for a circuit board structure, in order to form a build-up structure on the base substrate, dielectric films and conductive films are usually stacked sequentially on a base substrate, and the then conductive films are patterned. Then, the steps outlined above are repeated until the circuit board structure reaches the number of layers required for the design. However, although this method has high precision, the time required for the overall process will also increase with the number of layers of the build-up structure. In other words, this method is not conducive to the development of new processes or new materials that require rapid results. To this end, the present disclosure provides a method for manufacturing a circuit board structure by pre-fabricating multiple circuit layers, and then laminating the overlapping multiple circuit layers and multiple dielectric layers onto the base substrate. Thus, all the build-up structures can be completed at once.

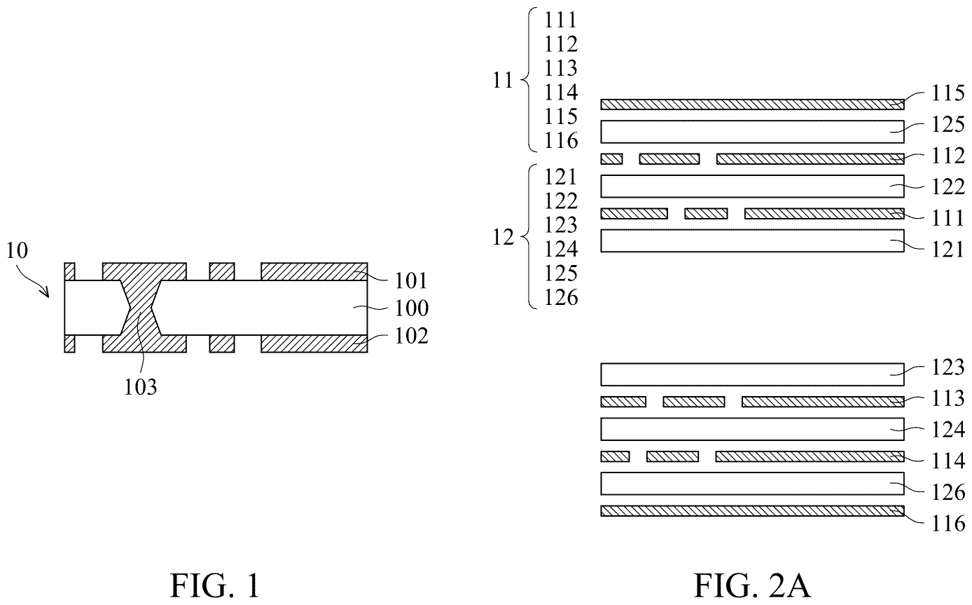

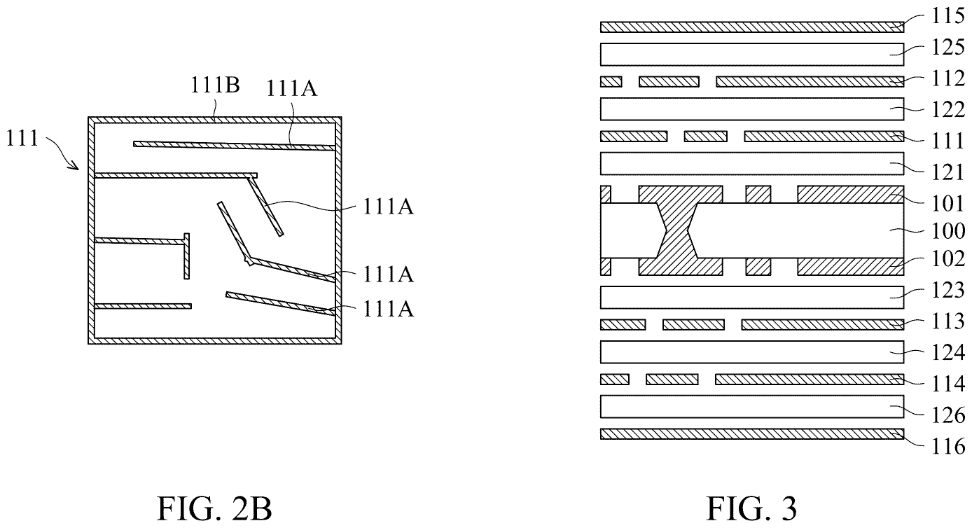

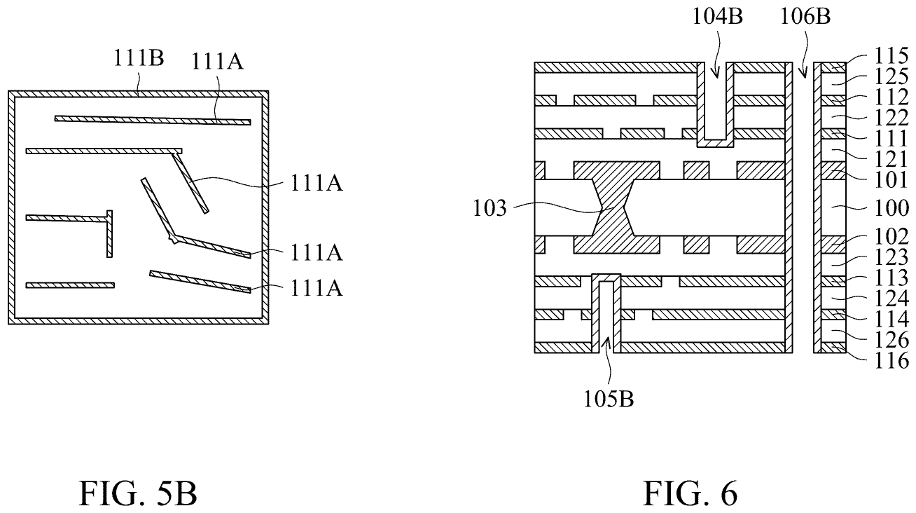

FIGS. 1, 2A, 3, 4, 5A, and 6 are schematic cross-sectional views showing the circuit board structure at different stages of the manufacturing method according to some embodiments of the present disclosure. In addition, FIGS. 2B and 5B are schematic top views showing the circuit layer at different stages of the manufacturing method according to some embodiments of the present disclosure. It should be noted that for clarity of explanation, some components of the circuit board structure are omitted in the drawings, and only some components are schematically illustrated. In some embodiments, additional components may be added to the circuit board structure described below. In other embodiments, some components of the circuit board structure described below may be replaced or omitted. It should be noted that in some embodiments, additional operational steps may be provided before, during, and/or after the method of forming the circuit board structure. In some embodiments, some of the steps described may be replaced or omitted, and the order of some of the steps described is interchangeable.

As shown in FIG. 1, a base substrate 10 is provided, wherein the base substrate includes a core layer 100, a first basic circuit layer 101, and a second basic circuit layer 102. Specifically, the core layer 100 is used to carry components disposed thereon (e.g., the first basic circuit layer 101, the second basic circuit layer 102, and other components) during the manufacturing process. In some embodiments, the material of the core layer 100 may be a prepreg containing polymer materials, fiber materials, or other suitable materials, but the present disclosure is not limited thereto. For example, the polymer material may include epoxy, polyimide (PI), polypropylene (PP), other suitable polymer materials, or combinations thereof, but the present disclosure is not limited thereto. For example, the fiber material may include carbon fiber, glass fiber, other suitable fiber materials, or combinations thereof, but the present disclosure is not limited thereto.

As shown in FIG. 1, the first basic circuit layer 101 is disposed on one side of the base layer 10, and the second basic circuit layer 102 is disposed on the core layer 100 relative to the first basic circuit layer 101. Specifically, the first basic circuit layer 101 and the second basic circuit layer 102 are used to transmit signals, such as control signals, image signals, sound signals, other suitable signals, or combinations thereof, but the present disclosure is not limited thereto. In some embodiments, the first basic circuit layer 101 or the second basic circuit layer 102 may include conductive material. For example, the conductive material may be aluminum (Al), copper (Cu), alloys thereof, or compounds thereof, but the present disclosure is not limited thereto. In some embodiments, the conductive material may be copper foil. For example, the copper foil may include brass, phosphor bronze, beryllium alloy, or oxygen-free copper, but the present disclosure is not limited thereto.

In some embodiments, the base substrate 10 may further include a first via 103 that penetrates the core layer 100 and electrically connects components on both sides of the core layer 100 (e.g., the first basic circuit layer 101 and the second basic circuit layer 102). In some embodiments, the first via 103 may include conductive material.

In some embodiments, the first basic circuit layer 101, the second basic circuit layer 102, and the first via hole 103 may be formed by a photolithography process, a plating process, other suitable processes, or combinations thereof, but the present disclosure is not limited thereto. For example, the photolithography process may include photoresist disposing (e.g., spin-on coating, lamination), soft baking, mask aligning, exposure, post-exposure baking, photoresist developing, rinsing, drying (e.g., spin-drying and/or hard baking), other suitable lithography techniques, or combinations thereof. For example, the plating process may include electroplating, electroless plating, other suitable plating technologies, or combinations thereof.

As shown in FIG. 2A, a plurality of conductive films (not shown) are provided and patterned to form the circuit layers 11. Specifically, the circuit layers 11 are used to transmit signals or implement specific functions. In some embodiments, the conductive films may include metal films, such as copper foils, but the present disclosure is not limited thereto. In some embodiments, the thickness of the metal films may be between 12 μm and 18 μm, but the present disclosure is not limited thereto. For example, the thickness of the metal films may be 12 μm, 14 μm, 16 μm, 18 μm, or any value or range between the above values.

In some embodiments, the process of patterning the conductive films may include a laser etching process, such as a solid-state laser, but the present disclosure is not limited thereto. Compared with using ordinary lasers, using the solid-state laser to pattern conductive films may avoid the craters that occur during the process of breaking down the conductive films. Therefore, the circuit layers produced by solid-state laser may have a certain degree of high precision and high flatness.

In some embodiments, the circuit layers 11 formed by the above process may include at least two circuit layers corresponding to one side of the base substrate 10. For example, the circuit layers 11 may include a first circuit layer 111 and a second circuit layer 112 corresponding to the first basic circuit layer 101, and these two circuit layers will be sequentially stacked on the first basic circuit layer 101 in subsequent steps. In other words, compared with the prior art method of “first placing a conductive film on a base substrate or a build-up structure, then using a solid-state laser to form the conductive film into a circuit layer, and repeating the steps outlined above”, the present disclosure is implanted by the following steps. Before the conductive films are disposed on the base substrate or build-up structure, at least two conductive films are formed into at least two circuit layers by solid-state laser, and at least two circuit layers are pressed together on one side of the base substrate 10 at one time in the subsequent process.

In some embodiments, the circuit layers 11 formed by the above process may further include at least two circuit layers corresponding to the other side of the base substrate 10. For example, the circuit layers 11 may further include a third circuit layer 113 and a fourth circuit layer 114 corresponding to the second basic circuit layer 102, and these two circuit layers will be sequentially stacked on the second basic circuit layer 102 in subsequent steps.

In some embodiments, the circuit layers 11 may also include more circuit layers according to requirements, such as the fifth circuit layer 115 and the sixth circuit layer 116 shown in FIG. 2A. The fifth circuit layer 115 may correspond to the first basic circuit layer 101, and the sixth circuit layer 116 may correspond to the second basic circuit layer 102.

In some embodiments, the material, thickness, shape of the circuit pattern, density of the circuit pattern, and other specifications (or parameters) of each circuit layer 11 may be the same or different. For example, the first circuit layer 111 and the second circuit layer 112 may be made of the same material but have different shapes of circuit patterns. Alternatively, the number of circuit layers corresponding to both sides of the base substrate 10 may also be different. For example, the number of circuit layers corresponding to the first basic circuit layer 101 of the base substrate 10 among the circuit layers 11 may be greater or smaller than the number of circuit layers corresponding to the second basic circuit layer 102 of the base substrate 10. In other words, asymmetric (e.g., different numbers) circuit layers may be formed on both sides of the base substrate 10.

In some embodiments, in order to facilitate extraction or transfer of the patterned conductive films (i.e., the circuit layers 11), the circuits in the patterned conductive films (i.e., the circuit layers 11) may be connected to each other. As shown in FIG. 2B, a top view of the first circuit layer 111 is used as an illustration. In some embodiments, the first circuit layer 111 includes a plurality of first portions 111A and a second portion 111B. Among them, the first portions 111A are long lines, the second portion 111B is a rectangular ring line, and the first portions 111A are connected to the second portion 111B. In other words, all the circuits of the first circuit layer 111 are physically connected to the second portion 111B, so as to facilitate the extraction or transfer of the entire first circuit layer 111 at one time. Of course, the number, shape, density, or relative position of the first portions 111A and the second portion 111B shown in FIG. 2B is only an example, and the present disclosure is not limited thereto. In other embodiments, the second portion 111B may also be a circular loop line, a triangular loop line, a polygonal loop line, a loop line with head and tail disconnected, or a circular with other suitable shapes.

In some embodiments, the second circuit layer 112 includes a plurality of third portions (not shown) and a fourth portion (not shown), and the fourth portion surrounds the third portions. Similarly, the third circuit layer 113 includes a plurality of fifth portions (not shown) and a sixth portion (not shown), and the sixth portion surrounds the fifth portions. Similarly, the fourth circuit layer 114 includes a plurality of seventh portions (not shown) and an eighth portion (not shown), and the eighth portion surrounds the seventh portions. The relationship between the two portions in each circuit layer may be similar or identical to the relationship between the two portions of the first circuit layer 111, therefore the descriptions thereof are omitted.

In some embodiments, each of the above-mentioned circuit layers 11 may be carried by a plurality of separators (not shown) to facilitate the transfer and stacking of these circuit layers on the first basic circuit layer 101 or on the second the basic circuit layers 102. In some embodiments, the separator may include mylar, other suitable materials, or a combination thereof, but the present disclosure is not limited thereto.

As shown in FIG. 2A, following the steps outlined above, a plurality of dielectric layers 12 are provided. Specifically, the dielectric layers 12 will form a build-up structure together with the circuit layers 11, and each dielectric layer 12 may be used to isolate the two circuit layers located on its upper and lower sides. In some embodiments, the dielectric layers 12 may include epoxy, polyimide, Ajinomoto buildup film (ABF), other suitable polymer materials, or combinations thereof, but the present disclosure is not limited thereto. In some embodiments, the thickness of each dielectric layers 12 is at least 35 μm to effectively achieve electrical isolation. For example, the thickness of the dielectric layers 12 may be 35 μm, 40 μm, 45 μm, 50 μm, 100 μm, or any value or range between the above values.

In some embodiments, the dielectric layers 12 may include at least two dielectric layers corresponding to one side of base substrate 10. For example, the dielectric layers 12 may include a first dielectric layer 121 and a second dielectric layer 122 corresponding to the first basic circuit layer 101, and these two dielectric layers will be sequentially stacked on the first basic circuit layer 101 in subsequent steps. Similarly, the dielectric layers 12 may further include at least two dielectric layers corresponding to the other side of the base substrate 10. For example, the dielectric layers 12 may further include a third dielectric layer 123 and a fourth dielectric layer 124 corresponding to the second basic circuit layer 102, and these two circuit layers will be sequentially stacked on the second basic circuit layer 102 in subsequent steps.

In some embodiments, the dielectric layers 12 may also include more circuit layers according to requirements, such as the fifth dielectric layer 125 and the sixth dielectric layer 126 shown in FIG. 2A. The fifth dielectric layer 125 may correspond to the first basic circuit layer 101, and the sixth dielectric layer 126 may correspond to the second basic circuit layer 102.

In some embodiments, the material, thickness, shape, and other specifications (or parameters) of each dielectric layer 12 may be the same or different. For example, the materials of the first dielectric layer 121 and the second dielectric layer 122 may be different. Alternatively, the number of dielectric layers corresponding to both sides of the base substrate 10 may also be different. For example, the number of dielectric layers corresponding to the first basic circuit layer 101 of the base substrate 10 may be greater or smaller than the number of dielectric layers corresponding to the second basic circuit layer 102 of the base substrate 10. In other words, asymmetric (e.g., different numbers) dielectric layers may be formed on both sides of the base substrate 10.

As shown in FIG. 3, following the steps outlined above, at least two dielectric layers and at least two circuit layers are stacked on one side of the base substrate 10. For example, the first dielectric layer 121, the first circuit layer 111, the second dielectric layer 122, and the second circuit layer 112 may be sequentially stacked on the first basic circuit layer 101. Among them, the first dielectric layer 121 and the first circuit layer 111 may jointly form a set of build-up structures, and the second dielectric layer 122 and the second circuit layer 112 may jointly form another set of build-up structures. In the present disclosure, a set of build-up structures may include at least one dielectric layer and at least one circuit layer.

However, the present disclosure is not limited thereto. In some embodiments, at least two dielectric layers and at least two circuit layers may be stacked on both sides of the base substrate 10 in the same step. For example, in addition to forming two sets of build-up structures on the first basic circuit layer 101, the third dielectric layer 123, the third circuit layer 113, the fourth dielectric layer 124, and the fourth circuit layer 114 may also be stacked on the second basic circuit layer 102 in sequence. Among them, the third dielectric layer 123 and the third circuit layer 113 may jointly form a set of build-up structures, and the fourth dielectric layer 124 and the fourth circuit layer 114 may jointly form another set of build-up structures.

Of course, the above-mentioned stacking manner or the number of build-up structures are only examples. For example, more dielectric layers and circuit layers, such as the fifth dielectric layer 125 and the fifth circuit layer 115, may be stacked on the second circuit layer 112. Similarly, more dielectric layers and circuit layers, such as the sixth dielectric layer 126 and the sixth circuit layer 116, may be stacked on the fourth circuit layer 114 in the same step.

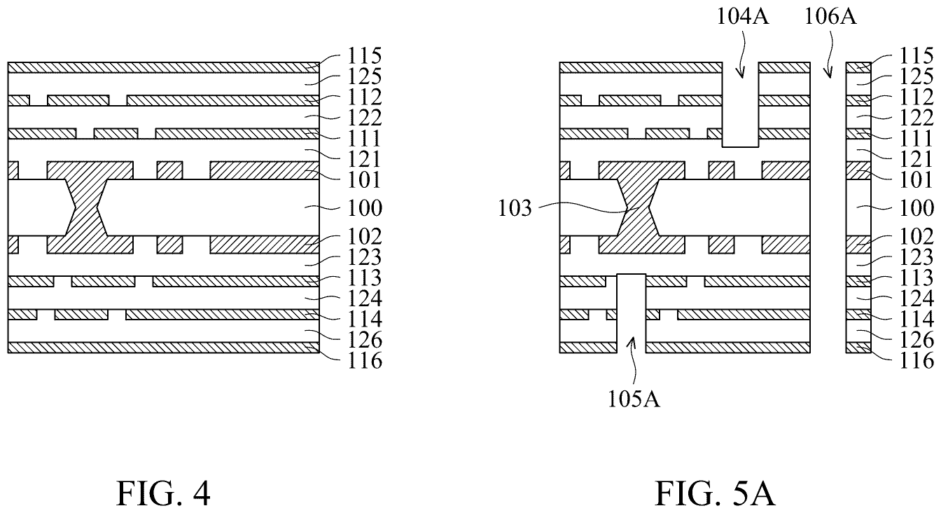

As shown in FIG. 4, following the steps outlined above, a lamination process is performed so that the first dielectric layer 121, the first circuit layer 111, the second dielectric layer 122, and the second circuit layer 112 are fixedly attached to the first basic circuit layers 101. In other words, the present disclosure greatly reduces the total time-consuming of the build-up process by laminating at least two or more sets of build-up structures at one time. Similarly, the third dielectric layer 123, the third circuit layer 113, the fourth dielectric layer 124, and the fourth circuit layer 114 may be fixedly attached to the second basic circuit layer 102 in the same lamination process.

It should be noted that the stacking method and the number of stacked layers in the steps outlined above are only examples and are not intended to limit the present disclosure. For a person having ordinary skill in the art, the number of dielectric layers and circuit layers that may be stacked and pressed in a single process depends on the type of material, design requirements, process capabilities, or other possible factors. For example, in some embodiments, m layers of dielectric layers and n layers of circuit layers may be laminated on one side of the base substrate 10 at one time. For example, m may be a positive integer between 2 and 10, n may be a positive integer between 2 and 10, and m may be greater than, equal to, or less than n. In some embodiments, a total of x dielectric layers and a total of y circuit layers may be pressed together on both sides of the base substrate 10 at one time. For example, x may be a positive integer between 3 and 20, y may be a positive integer between 3 and 20, and x may be greater than, equal to, or less than y.

In some embodiments, the above-mentioned lamination process may achieve a fixed adhesion effect through specific temperature and pressure. In other words, the manufacturing method for the circuit board structure of the present disclosure may omit adhesives such as copper paste, copper glue, etc. Of course, a person having ordinary skill in the art may also additionally provide adhesives in the circuit board structure according to needs, and the present is not limited to the above content.

In some embodiments, in order to make the circuit pattern perform a specific function, the circuit pattern in each circuit layer may be further adjusted by drilling. As shown in FIG. 5A, after the lamination process is performed, a drilling process is optionally performed to form a first blind hole 104A on one side of the base substrate 10. The first blind hole 104A may pass through the first dielectric layer 121, the first circuit layer 111, the second dielectric layer 122, the second circuit layer 112, and other layers located thereon (e.g., the fifth dielectric layer 125, the fifth circuit layer 115, etc.). In some embodiments, the drilling process may also form a second blind hole 105A on one side of the base substrate 10. The second blind hole 105A may pass through the third dielectric layer 123, the third circuit layer 113, the fourth dielectric layer 124, the fourth circuit layer 114, and other layers located thereon (e.g., the sixth dielectric layer 126, the sixth circuit layer 116, etc.). In some embodiments, the drilling process may also form a through hole 106A. Among them, the through hole 106A penetrates the entire circuit board structure.

As shown in FIG. 5B, a top view of the first circuit layer 111 is used as an illustration. In some embodiments, the first portions 111A and the second portion 111B of the first circuit layer 111 may be disconnected from each other by providing the first blind hole 104A. In addition, the first blind hole 104A may also disconnect the third portions and the fourth portion of the second circuit layer 112 from each other. Similarly, the second blind hole 105A may disconnect the fifth portions and the sixth portion of the third circuit layer 113 from each other, or disconnect the seventh portions and the eighth portion of the fourth circuit layer 114 from each other. In this way, the circuit patterns in each circuit layer may be further adjusted, and these circuit patterns may have predetermined functions.

In some embodiments, the drilling process may include mechanical drilling, chemical drilling, laser drilling, other suitable drilling techniques, or combinations thereof, but the present disclosure is not limited thereto. In some embodiments, the number, size, location, or other parameters of the first blind hole 104A, the second blind hole 105A, and the through hole 106A formed may be determined according to requirements. In some embodiments, the first blind hole 104A, the second blind hole 105A, and the through hole 106A may be formed simultaneously or successively in the same or different drilling processes.

In some embodiments, in order to electrically connect circuit patterns between different circuit layers, vias may be further formed by disposing conductive materials in blind holes or through holes. As shown in FIG. 6, after the drilling process is performed, a plating process is optionally performed to fill or cover these blind holes or through holes with conductive material. In this way, the first blind hole 104A may be formed into the second via 104B, the second blind hole 105A may be formed into the third via 105B, or the through hole 106A may be formed into the fourth via 106B. In some embodiments, the conductive material may include aluminum (Al), copper (Cu), alloys thereof, or compounds thereof, but the present disclosure is not limited thereto.

Through the steps outlined above, a circuit board structure may be obtained. In actual situations, the line accuracy of the circuit board structure formed by the steps outlined above may reach between 75 um±20% (that is, 75 um±15 um), which is sufficient for the development of new processes or new materials.

In summary, the present disclosure provides a manufacturing method for a circuit board structure. Specifically, the present disclosure completes multiple sets of build-up structures at one time by pre-fabricating multiple circuit layers, and then laminating the overlapping multiple circuit layers and multiple dielectric layers on the base substrate. In this way, the present disclosure realizes an extremely low-time-consuming method for manufacturing a circuit board structure, thereby significantly reducing the verification time during the development of new processes or new materials. In this case, the efficiency of new process development or new material development may be greatly increased.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A manufacturing method for a circuit board structure, comprising:
providing a basic substrate, wherein the basic substrate comprises:
a core layer; and
a first basic circuit layer disposed on the core layer;
patterning a plurality of conductive films to form a plurality of circuit layers, wherein the plurality of circuit layers comprise a first circuit layer and a second circuit layer;
providing a plurality of dielectric layers, wherein the plurality of dielectric layers comprise a first dielectric layer and a second dielectric layer;
sequentially stacking the first dielectric layer, the first circuit layer, the second dielectric layer, and the second circuit layer on the first basic circuit layer; and
performing a lamination process so that the first dielectric layer, the first circuit layer, the second dielectric layer, and the second circuit layer are fixedly attached to the first basic circuit layer.

2. The manufacturing method for the circuit board structure as claimed in claim 1, wherein after performing the lamination process, the method further comprises:
performing a drilling process so that the first circuit layer comprises a first portion and a second portion that are disconnected from each other and the second circuit layer comprises a third portion and a fourth portion that are disconnected from each other.

3. The manufacturing method for the circuit board structure as claimed in claim 2, wherein the second portion surrounds the first portion, and the fourth portion surrounds the third portion.

4. The manufacturing method for the circuit board structure as claimed in claim 2, wherein the first portion or the third portion is a long line, and the second portion or the fourth portion is a rectangular ring line, a circular loop line, a triangular loop line, a polygonal loop line, or a loop line with head and tail disconnected.

5. The manufacturing method for the circuit board structure as claimed in claim 1, wherein the basic substrate further comprises a second basic circuit layer, and the second basic circuit layer is disposed on the core layer relative to the first basic circuit layer.

6. The manufacturing method for the circuit board structure as claimed in claim 5, wherein the plurality of circuit layers comprise a third circuit layer and a fourth circuit layer, the plurality of dielectric layers further comprise a third dielectric layer and a fourth dielectric layer, and the manufacturing method for the circuit board structure further comprises:
sequentially stacking the third dielectric layer, the third circuit layer, the fourth dielectric layer, and the fourth circuit layer on the second basic circuit layer; and
performing the laminating process so that the third dielectric layer, the third circuit layer, the fourth dielectric layer, and the fourth circuit layer are fixedly attached to the second basic circuit layer.

7. The manufacturing method for the circuit board structure as claimed in claim 6, wherein after performing the lamination process, the method further comprises:
performing a drilling process so that the third circuit layer comprises a fifth portion and a sixth portion that are disconnected from each other and the fourth circuit layer comprises a seventh portion and an eighth portion that are disconnected from each other.

8. The manufacturing method for the circuit board structure as claimed in claim 7, wherein the sixth portion surrounds the fifth portion, and the eighth portion surrounds the seventh portion.

9. The manufacturing method for the circuit board structure as claimed in claim 1, wherein after patterning the plurality of conductive films, the plurality of circuit layers are carried by a plurality of spacers to stack the plurality of circuit layers on the first basic circuit layer.

10. The manufacturing method for the circuit board structure as claimed in claim 1, wherein a process of patterning the conductive films comprises a laser etching process.

11. The manufacturing method for the circuit board structure as claimed in claim 10, wherein the laser etching process comprises a solid-state laser.

12. The manufacturing method for the circuit board structure as claimed in claim 1, wherein a thickness of the plurality of conductive films is between 12 μm and 18 μm.

13. The manufacturing method for the circuit board structure as claimed in claim 1, wherein a thickness of the plurality of dielectric layers is at least 35 μm.

14. The manufacturing method for the circuit board structure as claimed in claim 1, wherein the step of performing a lamination process comprises laminating m layers of the plurality of dielectric layers and n layers of the plurality of circuit layers on one side of the base substrate at one time, wherein m is a positive integer between 2 and 10, and n is a positive integer between 2 and 10.

15. The manufacturing method for the circuit board structure as claimed in claim 14, wherein m is equal to n.

16. The manufacturing method for the circuit board structure as claimed in claim 1, wherein the step of performing a lamination process comprises laminating a total of x layers of the plurality of dielectric layers and a total of y layers of the plurality of circuit layers on both sides of the base substrate at one time, x is a positive integer between 3 and 20, and y is a positive integer between 3 and 20.

17. The manufacturing method for the circuit board structure as claimed in claim 16, wherein x is equal to y.

18. The manufacturing method for the circuit board structure as claimed in claim 16, wherein a different number of dielectric layers are formed on two sides of the base substrate.

19. The manufacturing method for the circuit board structure as claimed in claim 16, wherein a different number of circuit layers are formed on both sides of the base substrate.

20. The manufacturing method for the circuit board structure as claimed in claim 1, wherein the step of the lamination process is implemented without an adhesive.
